(19) United States
(12) Patent Application Publication
(10) Pub. No.: US 2008/0006440 A1
(43) Pub. Date: Jan. 10, 2008

(54) PROCESS FOR MANUFACTURING AN INJECTION MOLDED PART WITH INTEGRATED FLEXIBLE PRINTED CIRCUIT BOARD

(76) Inventor: Hans-Georg HUONKER, Villingen-Schwenningen (DE)

Correspondence Address: MCGLEW & TUTTLE, PC, P.O. BOX 9227, SCARBOROUGH STATION, SCARBOROUGH, NY, 10510-9227, US

(21) Appl. No.: 11/765,663

(22) Filed: Jun. 20, 2007

(30) Foreign Application Priority Data
Jun. 21, 2006 (DE) DE 102006028816.5

(51) Int. Cl. H05K 1/00; B28B 5/00

(52) U.S. Cl. 174/254; 264/241; 425/116

(57) ABSTRACT

A process and manufacturing system for manufacturing injection molded parts with integrated flexible printed circuit board (9), provided with a cover (39/47) of plastic, fixed in a recess (2) of a carrier strip (1) by projecting carrier elements (14, 15, 16, 17). A circuit board (9) fixed in the carrier strip (1) is inserted into the cavity (21) of first casting mold half (20) of an injection mold, held in position by the carrier elements (14 through 17). The cavity (21) of the first casting mold half is closed by a closing mold part, which has no cavity, including the printed circuit board (9), and the cavity (21) is filled with injection molding compound in a first casting operation. The closing mold part (35) is removed and replaced with a second casting mold half (45) with a cavity (46), which is filled with injection molding compound in a second casting operation.

### CROSS REFERENCE TO RELATED APPLICATIONS

This application claims the benefit of priority under 35 U.S.C. §119 of German Patent Application DE 10 2006 028 816.5 filed Jun. 21, 2006, the entire contents of which are incorporated herein by reference.

### FIELD OF THE INVENTION

The present invention pertains to a process for manufacturing an injection molded part with integrated flexible printed circuit board.

### BACKGROUND OF THE INVENTION

The extrusion coating of flexible printed circuit boards has been known from the state of the art for a long time. Individual flexible printed circuit boards are introduced into a cavity and extrusion coated with a plastic. To accurately define the location of such flexible printed circuit boards in the later finished plastic component or in the cover thereof, it is necessary to introduce corresponding fixing means into the cavity, doing so such that the flexible printed circuit board is not deformed and/or does not change its position unacceptably.

The processes and procedures known so far, especially in automatic manufacture, are extremely complicated, on the one hand, because additional fixing means must be provided within the cavity, and, on the other hand, because a handling means is to be provided, by means of which the individual flexible printed circuit boards can be fed to the injection molding machine.

### SUMMARY OF THE INVENTION

Accordingly, the basic object of the present invention is to provide a process that makes it possible to provide flexible printed circuit boards as finished plastic components with a cover consisting of plastic in a work process taking place as a continuous or stepwise process.

The object is accomplished according to the present invention by
a) fixing the flexible printed circuit boards to be provided with a cover consisting of plastic by means of carrier elements projecting at the edge in a recess of a carrier strip with spaces on all sides,
b) inserting one of the printed circuit boards fixed in the carrier strip into the cavity of the casting mold half of an injection mold with spacing on all sides and by holding same by the carrier elements in a predetermined position,
c) closing the cavity of the casting mold half by means of a closing mold part, which has no cavity, including the printed circuit board, and filling the cavity with injection molding compound in a first casting operation and
d) removing the closing mold part and replacing it with a second casting mold half with a cavity, which corresponds to the rest of the cover and which is filled with injection molding compound in a second casting operation.

A flexible printed circuit board can be processed with the process according to the present invention into a finished plastic component in a manufacturing process taking place continuously or stepwise, and it is guaranteed that the printed circuit boards always assume the same predetermined position in the finished plastic parts. With the carrier strip used now, in the cavity of which the printed circuit boards are accommodated, it is also possible in a simple manner to position and hold the printed circuit boards in the respective casting mold. The dimensions of these recesses are adapted to the dimensions of the surface shape of the flexible printed circuit boards and of the casting mold such that the printed circuit board can be completely extrusion-coated.

To make it possible to fasten the printed circuit boards on the carrier strip in a simple manner and in a secure position, the lateral edges of the printed circuit boards are provided with outwardly projecting carrier elements designed as mounting tabs. To receive the carrier elements, i.e., the mounting tabs, in a position-fixing manner, the components that limit the recesses of the carrier strip and are in the form of longitudinal and cross bands are provided with depressions each. To obtain a rigid and reliable connection to the carrier strip, the mounting tabs are bonded or welded to the longitudinal or cross bands.

A plurality of flexible printed circuit boards to be extrusion-coated can thus be arranged one after another and fixed in the recesses of the carrier strip, which are present as multiple recesses in rows, so that they can be fed one after another to a correspondingly designed injection mold in a work process taking place stepwise.

Due to the fact that the printed circuit boards are extrusion-coated with a first cover half one after another on one flat side only in a first casting operation, the risk that the printed circuit board is exposed to strong, destructive compressive forces acting on one side during such an injection operation is extensively avoided by the printed circuit board being able to be in contact with and supported on the flat side located opposite the cavity at a back pressure surface.

It may be advantageous in this connection if vacuum can be applied to the flat mold part of the injection molding cavity to fix the printed circuit board, so that the flexible printed circuit board is pulled against the wall of this flat mold half of the injection mold cavity. A half of the cover is injected around the flexible printed circuit board during the subsequent injection molding operation.

A second half of the cover is injected on the top side on the flexible printed circuit board and on the first half of the cover in a second injection molding operation, so that a finished component with integrated flexible printed circuit board is subsequently obtained.

Based on the carrier strip with the flexible printed circuit boards arranged snugly thereon, the manufacture of a plastic component with integrated printed circuit board can be manufactured in a continuous work operation progressing stepwise.

The individual process steps of the process according to the present invention will be explained in more detail below as an example on the basis of the drawings. The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which a preferred embodiment of the invention is illustrated.

### BRIEF DESCRIPTION OF THE DRAWINGS

In the drawings:

FIG. 1 is a perspective exploded view of a section of a punched carrier strip together with a flexible printed circuit board;

FIG. 2 is a perspective view showing the carrier strip section from FIG. 1 with a plurality of printed circuit boards placed thereon;

FIG. 3 is a perspective view showing a half of a casting mold with a cavity, which is used to inject a half of a cover on a flexible printed circuit board;

FIG. 4 is a schematic perspective view showing the half of the casting mold from FIG. 3 with the attached carrier strip section according to FIG. 2 and with a closing mold part not yet located in the closing position;

FIG. 5 is a perspective view of a the carrier strip section from FIG. 4 with two printed circuit boards injection-coated on the underside offset by a transport step compared to FIG. 4;

FIG. 6 is a schematic perspective view showing the carrier strip section from FIG. 5 with a completely injection-coated printed circuit board on the underside and the top side and with a printed circuit board injection-coated on the underside only, which is in a second casting mold part, which is provided with a closing mold part having a cavity for the upper cover; and

FIG. 7 is a schematic perspective exploded view showing a double injection mold with two printed circuit boards injection-coated on one side.

### DESCRIPTION OF THE PREFERRED EMBODIMENT

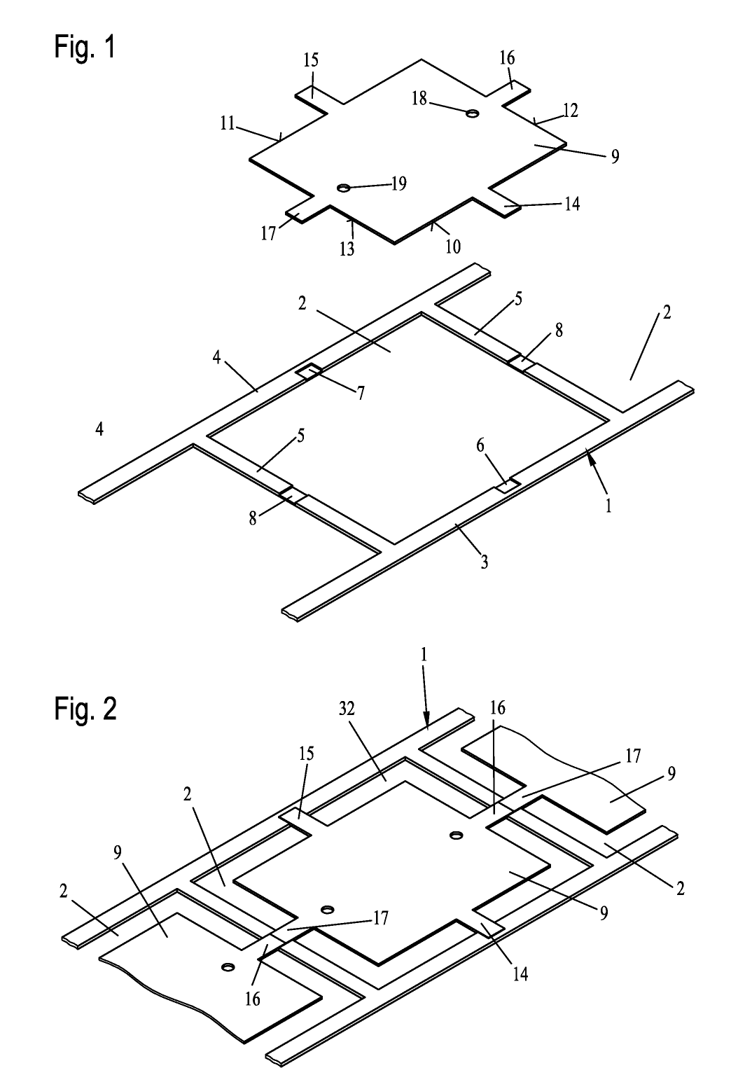

Referring to the drawings in particular, FIG. 1 shows a carrier strip 1, which may be manufactured, for example, from a paper web, a metal web or another thin, flexible material. This carrier strip 1 could also be manufactured from a plastic band. As is shown in FIG. 1, this carrier strip 1 is provided with a plurality of recesses 2, which have a square surface shape in the present exemplary embodiment. Due to these recesses 2, the carrier strip 1 forms two longitudinal bands 3 and 4, which extend in parallel to one another and are connected to one another by a plurality of cross bands 5. The longitudinal bands 3 are provided with impressed depressions 6 and 7 in the middle between two cross bands 5. The cross bands 5 have a depression 8 each approximately in the middle between the two longitudinal bands 3 and 4.

The recesses 2 are used to receive a flexible printed circuit board 9, which is provided in this exemplary embodiment with carrier elements each in the form of an outwardly projecting mounting tab 14, 15, 16 and 17, respectively, at the edge, i.e., at their lateral edges 10 and 11 as well as 12 and 13 extending longitudinally and crosswise. In addition, the flexible printed circuit board 9 has two holes 18 and 19 within its base between the two mounting tabs 16 and 17.

The printed circuit board 9 is present as multiple printed circuit boards corresponding to the number of recesses 2 of the carrier strip 1, into which [recesses] it is inserted.

As is apparent from FIG. 2, the flexible printed circuit boards 9 are arranged individually in one of the recesses 2 of the carrier strip 1. It can also be recognized that the lateral edges 10 through 13 have a lateral distance from the longitudinal and cross bands 3, 4 and 5 of the carrier strip 1.

The mounting tabs 14 and 15 fittingly protrude into the respective associated depressions 6 and 7 of the longitudinal bands 3 and 4. By contrast, the mounting tabs 16 and 17 protrude fittingly into the depressions 8 of the cross bands 5 in the mounted state, as this is apparent from FIG. 2. In this position shown in FIG. 2, the printed circuit boards 9 are fixed snugly at the longitudinal bands 3, 4 and the cross bands 5 via their mounting tabs 14, 15, 16 and 17, for example, by means of a bonded connection or a welded connection or another type of connection that can be established essentially automatically. Thus, the use of a carrier strip 1, which is provided with recesses 2, into which a printed circuit board 9 each can be individually inserted, also belongs to the process according to the present invention. The mounting tabs 14, 15, 16 and 17 made integrally in one piece with the printed circuit boards 9 are used at first to center the printed circuit boards 9 in a recess 2 at an essentially equal distance all around from the longitudinal and cross bands 3, 4 and 5, the mounting tabs 14 through 17, seated fittingly in the depressions 6, 7 and 8 of the carrier strip 1, being fastened in these depressions 6, 7 and 8 by a connection that is preferably a connection in substance, such as bonding or welding. Thus, the carrier strip provided with the printed circuit boards 9 forms an “endless band” of flexible printed circuit boards 9 arranged one after another in rows, so that these printed circuit boards 9 can be extrusion-coated in a machining process taking place continuously stepwise to form a finished component.

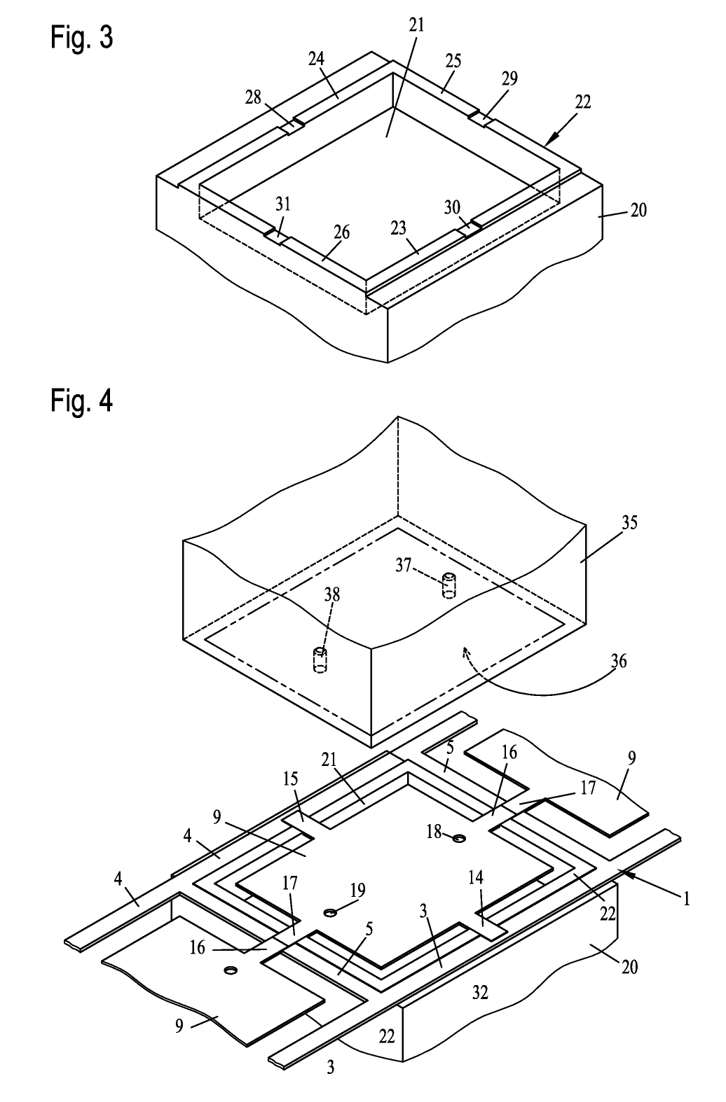

FIG. 3 shows for this, as an example and a schematically simplified form, an embodiment of a lower casting mold half 20, which has an inner cavity 21, whose shape corresponds to the outer contour of a half of a later cover half 39. The casting mold half 20 is provided in this exemplary embodiment with a circumferential [sic-Tr.Ed.] edge web 22 projecting upwardly approximately by the thickness of the carrier strip 1. The edge web is divided into longitudinally extending sections 23 and 24 as well as into transversely extending sections 25 and 26. Depressions 28, 29, 30 and 31 are arranged centrally in these sections 23, 24, 25 and 26. These depressions 28, 29, 30 and 31 are coordinated with the mounting tabs 14 through 17 in terms of both their surface shape and their depth, so that they receive the sections of the mounting tabs 14 through 17 located within the longitudinal and cross bands of the carrier strip with a flush surface and in a laterally fitting manner and they can as a result fix the position of a printed circuit board 9 in the cavity of the casting mold half.

The recesses 2 are dimensioned such that they can receive the circumferential edge web 22. The internal dimensions of the cavity 21 and of the circumferential edge web 22 are in turn selected to be such that a sufficient distance, which permits a sufficiently thick-walled extrusion coating of these lateral edges 10 through 13, is left between their lateral inner surfaces and the lateral edges 10 through 13.

To make it possible to close this first lower casting mold half 20 for a first casting operation, by which the underside cover half 39 is produced, a second upper casting mold half 35 is provided, which has a lower, flat limiting surface 36 towards the first casting mold half 20 in this exemplary embodiment. Two cylindrical holes 37, whose arrangement is congruent to the two holes 18 and 19 of the printed circuit board 9, are provided in this limiting surface 36 in this exemplary embodiment.

Thus, after closing the injection mold, consisting of the two casting mold halves 20 and 35, the printed circuit board 9 is thus flatly in contact on the top side with the flat limiting surface 36 of the upper casting mold half 35. To ensure during the subsequent injection molding operation that the printed circuit board 9 will come into and remain flatly in contact with this limiting surface 36, vacuum channels (not shown in the drawing), via which the printed circuit board 9 is suctioned onto the limiting surface 36 during the injection molding operation, may be provided in the upper casting mold half 35.

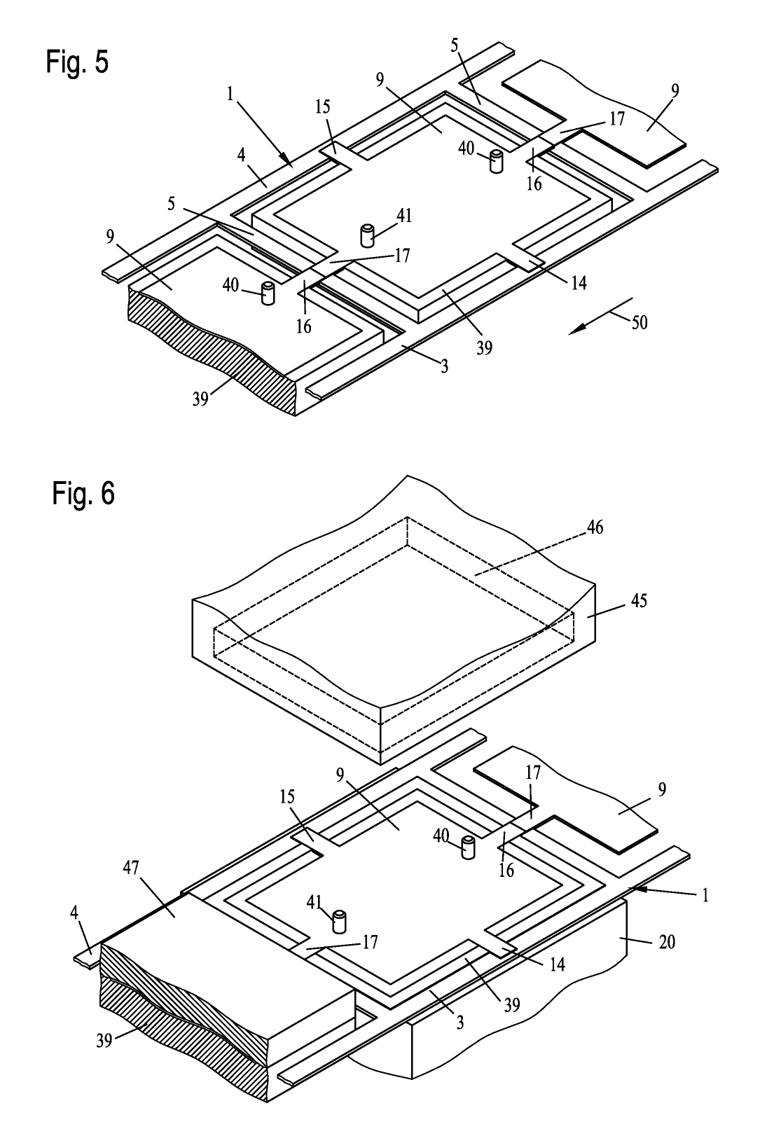

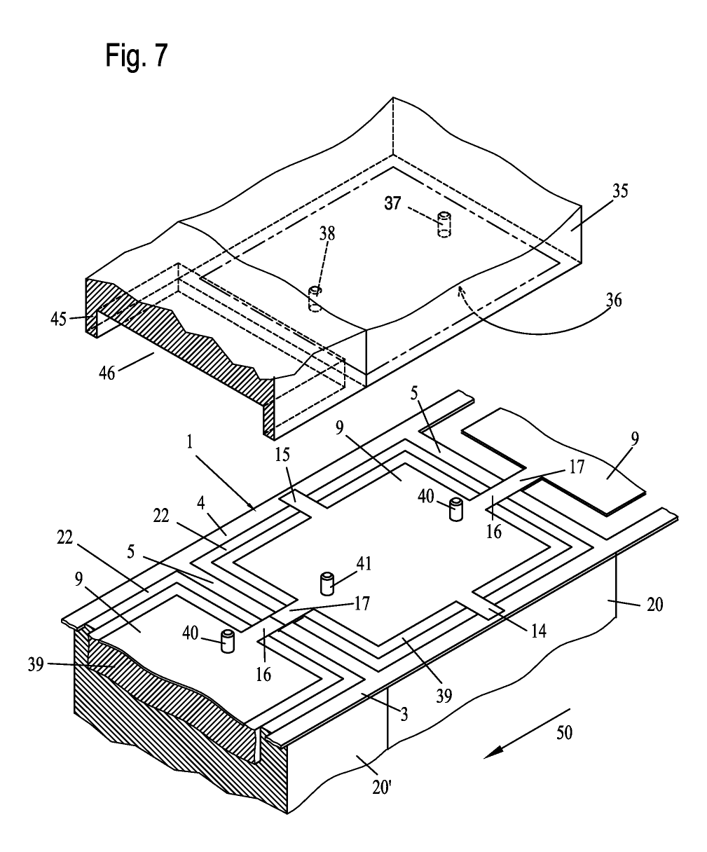

A first lower cover half 38 is injected onto the printed circuit board 9 in this first injection molding operation, as this is apparent especially from FIGS. 5 and 7.

FIG. 5 shows a section of a carrier strip 1 with a total of three printed circuit boards 9 in a position in which the first, underside cover has just been injected onto the middle printed circuit board 9 and the middle of the carrier strip 1 after a first casting operation and the carrier strip 1 is in a state immediately before performing another transport step to take place in the direction of arrow 50. The left-hand printed circuit board 9 of FIG. 5 has already been extrusion-coated with the underside cover half 39 before this casting operation and the transport step that had preceded it.

The right-hand printed circuit board 9 is shown in a state in which it has not yet been extrusion-coated. FIG. 5 also shows that two upwardly projecting coupling pins 40 and 41 are injected simultaneously during the injection molding operation through the cylindrical holes 37 and 38 provided in the upper casting mold half 35. Furthermore, FIG. 5 shows that the mounting tabs 14, 15, 16 and 17 pass outwardly through the lower cover half 38 and continue to be rigidly connected to the carrier strip 1.

After injecting this first cover half 39, the upper casting mold half 35 is removed and replaced with a second upper casting mold half 45, which is shown schematically in FIG. 6. This second upper casting mold half 45 has a second cavity 46, which is open towards the printed circuit board 9, which is located under it and is already provided with the first cover half 39, the dimensions of the second cavity 46 approximately corresponding to the cavity 21 of the lower casting mold half 20 according to FIG. 3. After closing the two casting mold halves 20 and 45, the upper cover half 47 can now be injected onto the lower cover half 39 and to the printed circuit board 9. The printed circuit board is now completely enclosed by the two cover halves 39 and 47, as this can be recognized especially from FIG. 6 for the front printed circuit board 9 shown in a perspective partial section. An additional connection now becomes established between the two cover halves 39 and 47 via the coupling pins 41, which can also be recognized from FIG. 6.

After this process step of injecting the second cover half 47, the mounting tabs 14, 15, 16 and 17 can again be separated from the carrier strip 1 and removed if they laterally project from the cover 39/47, so that the finished component provided with an integrated printed circuit board 9 is now obtained.

While it is necessary in the working method just described to carry out the injection of the two cover halves 39, 47 in separate casting molds or in casting molds with replaceable upper casting mold halves 35 and 45, FIG. 7 shows a double casting mold, in which the lower cover half 39 and the upper cover half 47 can be prepared in work cycles immediately following each other after an intermediate transport step. This double casting mold has an additional lower casting mold part 20′, which has a cavity 39′, which can fittingly accommodate the lower cover half 39 injected in the casting mold half 20, immediately adjacent to the first lower casting mold half 20 in the transport direction indicated by arrow 50. An upper casting mold half 45 with its cavity 46 can be attached closingly to this additional mold part. While the lower cover half is being formed in the casting mold half 20 with the attached closing mold part 35, the upper cover half 47 can be produced next to it in the casting mold part 45 at the same time.

Highly efficient manufacture is thus achieved.

While a specific embodiment of the invention has been shown and described in detail to illustrate the application of the principles of the invention, it will be understood that the invention may be embodied otherwise without departing from such principles.

What is claimed is:

1. A process for manufacturing injection molded parts with integrated flexible printed circuit board, the process comprising the steps of:
fixing flexible printed circuit boards, to be provided with a cover of plastic, in a recess of a carrier strip by means of carrier elements projecting at the edge of the circuit boards at a distance on all sides;
inserting each one of the printed circuit boards, fixed in said carrier strip, into a respective cavity of a casting mold half of an injection mold at a distance on all sides and held in a predetermined position by said carrier elements;
closing said cavity of a casting mold half by means of a closing mold part, which has no cavity;
filling said cavity, with said printed circuit board disposed therein, with injection molding compound in a first casting operation;
removing the closing mold part;
replacing the removed closing mold part with a second casting mold half having a cavity; and
filling the cavity of the second casting mold half with injection molding compound in a second casting operation.

2. A process in accordance with claim 1, wherein only a flat side as well as lateral edges of the printed circuit board are extrusion coated in the first casting operation.

3. A process in accordance with claim 1, wherein the filling of said cavity of said second casting mold half is carried out in a second casting mold, which is offset in relation to said first casting mold half by a transport step of said carrier strip.

4. A process in accordance with claim 1, wherein said printed circuit board is supported on an essentially flat limiting surface of a closing mold part during the first casting operation.

5. A process in accordance with claim 4, wherein said printed circuit board is pneumatically suctioned onto the limiting surface of the closing mold part during the first casting operation.

6. A process in accordance with claim 3, wherein the transport steps of the carrier strip each correspond to a center distance between two consecutive printed circuit boards.

7. A process in accordance with claim 1, wherein the carrier strip has recesses and area dimensions of said recesses are larger on all sides than an area of the printed circuit board to be received therein.

8. A process in accordance with claim 7, wherein the area dimensions of said recesses are larger on all sides than an edge web enclosing the cavity of the first casting mold half, in an elevated position.

9. A process in accordance with claim 1, wherein said carrier elements comprise outwardly projecting mounting tabs, each at an edge of the printed circuit board.

10. A process in accordance with claim 7, wherein said recesses have a rectangular surface shape and are limited by contiguous, parallel longitudinal bands and cross bands extending at right angles thereto.

11. A process in accordance with claim 10, wherein said longitudinal bands and said cross bands are provided with depressions in the middle of said recesses for receiving the mounting tabs with a flush surface.

12. A process in accordance with claim 11, wherein said mounting tabs are bonded or welded in said depressions to said longitudinal and cross bands.

13. A process in accordance with claim 4, wherein a double casting mold is provided, which includes the casting mold half with the cavity and the corresponding closing mold part with a liming surface for producing a first cover half and which is provided for producing a second cover half with an additional mold half which has a cavity receiving the first cover half and can be closed by an additional attachable mold part, which is equipped with the cavity for the second cover half.

14. A process in accordance with claim 13, wherein the casting mold parts for the first and second cover halves are arranged each directly next to each other.

15. An injection molded part with integrated flexible printed circuit board manufacturing system, the system comprising:
a plurality of flexible printed circuit boards, to be provided with a cover of plastic, each of the printed circuit boards having carrier elements projecting at the edge of the circuit boards at a distance on all sides;
a carrier strip with a carrier frame defining recesses, each recess for carrying one of the printed circuit boards via the carrier elements projecting at the edge of the circuit boards;
a first casting mold half of an injection mold with a cavity, said carrier strip positioning one of the printed circuit boards into the cavity with a distance on all sides and held in a predetermined position;
a closing mold part, the cavity of the casting mold half being closed by the closing mold part, the a closing mold part having no cavity;
means for filling the cavity with injection molding compound; and
a second casting mold half having a second mold half cavity, said closing mold part being removed after the first casting mold half cavity is filled the with injection molding compound and replaced with the second casting mold half, the means for filling the cavity of the second casting mold half with injection molding compound.

16. A manufacturing system in accordance with claim 15, further comprising suction means wherein said first casting mold half has an essentially flat limiting surface for supporting each of the printed circuit boards and each printed circuit board is pneumatically suctioned onto the limiting surface of the closing mold part during a first casting operation.

17. A manufacturing system in accordance with claim 15, further comprising means for moving the carrier strip wherein the transport steps of the carrier strip each correspond to a center distance between two consecutive printed circuit boards, wherein the carrier strip has recesses and area dimensions of said recesses are larger on all sides than an area of the printed circuit board to be received therein and the area dimensions of said recesses are larger on all sides than an edge web enclosing the cavity of the first casting mold half, in an elevated position.

18. A manufacturing system in accordance with claim 15, wherein
said carrier elements comprise outwardly projecting mounting tabs, each at an edge of the printed circuit board;
the recesses have a rectangular surface shape and are limited by contiguous, parallel longitudinal bands and cross bands extending at right angles thereto; and
the longitudinal bands and said cross bands are provided with depressions in the middle of said recesses for receiving the mounting tabs.

19. A manufacturing system in accordance with claim 15, wherein a double casting mold is provided, which includes the casting mold half with the cavity and the corresponding closing mold part with a liming surface for producing a first cover half and which is provided for producing a second cover half with an additional mold half which has a cavity receiving the first cover half and can be closed by an additional attachable mold part, which is equipped with the cavity for the second cover half, wherein the casting mold parts for the first and second cover halves are arranged one following the other.
